(19) United States
(12) Patent Application Publication
(10) Pub. No.: US 2023/0354552 A1
(43) Pub. Date: Nov. 2, 2023

(54) ASSEMBLY STRUCTURE OF VAPOR CHAMBER AND HEAT PIPE

(71) Applicant: TAIWAN MICROLOOPS CORP., New Taipei City (TW)

(72) Inventor: Chun-Hung LIN, New Taipei City (TW)

(21) Appl. No.: 17/891,118

(22) Filed: Aug. 18, 2022

(30) Foreign Application Priority Data
Apr. 28, 2022 (TW) 111116252

(51) Int. Cl. H05K 7/20

(52) U.S. Cl. CPC H05K 7/20309; H05K 7/20336

(57) ABSTRACT

An assembly structure of a vapor chamber and a heat pipe includes a vapor chamber half housing, multiple heat pipe half housings, a half housing covering component, a capillary structure, and a working fluid. The vapor chamber half housing has a bottom plate and a lower surrounding plate. A vapor chamber room is enclosed between the bottom plate and the lower surrounding plate, and the lower surrounding plate has multiple lower engaging half rings. The heat pipe half housings are connected to the lower engaging half rings. The half housing covering component is connected and sealed with the vapor chamber half housing and the heat pipe half housings. The capillary structure is continuously disposed on the vapor chamber half housing and the heat pipe half housings and disposed in the vapor chamber room and the heat pipe rooms.

### TECHNICAL FIELD

The present disclosure relates to a heat dissipater technology, particularly to an assembly structure of a vapor chamber and a heat pipe.

### DESCRIPTION OF RELATED ART

With the power-on speed of a computer and the reading speed of software being accelerated, the heat and the temperature generated when internal electronic units are operating are higher and higher. The high temperature may cause most of the electronic units to rapidly deteriorate, and the reading and writing speed of the electronic unit, such as a solid-state drive, may be lowered. As such, how to maintain the working temperature is the issue to be improved by the present disclosure.

For solving the heat dissipating problem of the electronic units, high-performance heat dissipating components, such as a heat pipe and a vapor chamber, have been developed. The above-mentioned heat dissipating components have advantages of lightweight and having a high-performance heat dissipating capability, thus the above-mentioned components become the popular heat dissipating components for the electronic units.

However, a lot of molds are required to be prepared during the manufacturing procedure to perform processes, for example, a punching, a feeding, and an edge folding. The installation of a capillary structure plays an important role relative to the capillary absorbing capability. For the related-art vapor chamber and the heat pipe, the capillary structure is mostly manufactured independently, and then the capillary structure in the vapor chamber and the capillary structure in each heat pipe are mutually connected with a secondary processing method. As such, the capillary absorbing capability is not good enough because the above-mentioned capillary structure is not a continuous structure. Moreover, the manufacturing procedure of the assembly structure of the vapor chamber and the heat pipe is complicated and labor consuming, thus the procedure may not satisfy the current operation requirements.

Accordingly, the applicant of the present disclosure has devoted himself for improving the mentioned disadvantages.

### SUMMARY OF THE DISCLOSURE

The present disclosure is to provide an assembly structure of a vapor chamber and a heat pipe, which has advantages of being easily manufactured and making a capillary structure be evenly distributed to enhance a capillary absorbing capability.

Accordingly, the present disclosure provides an assembly structure of a vapor chamber and a heat pipe, which includes a vapor chamber half housing, a plurality of heat pipe half housings, a half housing covering component, a capillary structure and a working fluid; the vapor chamber half housing includes a bottom plate and a lower surrounding plate upwardly extended from the bottom plate, a vapor chamber room is enclosed between the bottom plate and the lower surrounding plate, and a plurality of lower engaging half rings are disposed on the lower surrounding plate; each of the heat pipe half housings is correspondingly connected to each of the lower engaging half rings, each of the heat pipe half housings has a heat pipe room, and each of the heat pipe rooms communicates with the vapor chamber room; the half housing covering component is correspondingly connected and sealed with the vapor chamber half housing and each of the heat pipe half housings; the capillary structure is continuously disposed on the vapor chamber half housing and each of the heat pipe half housings and formed in the vapor chamber room and each of the heat pipe rooms; and the working fluid is filled in the vapor chamber room.

Advantages achieved by the present disclosure are as follows. The vapor chamber half housing cover and the vapor chamber half housing are interchangeable or commonly shared, each of the heat pipe half housing covers and each of the heat pipe half housings are interchangeable or commonly shared, thereby the expenditure for fabricating molds being greatly saved and a storage management cost being lowered. With a plate thickness of each of the heat pipe half housings being less than a plate thickness of the vapor chamber half housing, each of the heat pipe half housings has bigger heat pipe room to increase the heat dissipating performance.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing an assembly structure of vapor chamber and heat pipe according to the present disclosure;

FIG. 2 is an exploded view showing the vapor chamber half housing, each of the heat pipe half housings and the half housing covering component according to the present disclosure;

FIG. 3 is a schematic view showing the assembly of the vapor chamber half housing and each of the heat pipe half housings according to the present disclosure;

FIG. 4 is a cross sectional exploded view showing the vapor chamber half housing, each of the heat pipe half housings and the half housing covering component according to the present disclosure;

FIG. 5 is a cross sectional view showing the assembling status of the assembly structure of vapor chamber and heat pipe according to the present disclosure;

FIG. 6 is a partially enlarged view of FIG. 5; and

FIG. 7 is a cross sectional view according to another embodiment of the present disclosure.

### DETAILED DESCRIPTION OF THE DISCLOSURE

The technical contents of this disclosure will become apparent with the detailed description of embodiments accompanied with the illustration of related drawings as follows. It is intended that the embodiments and drawings disclosed herein are to be considered illustrative rather than restrictive.

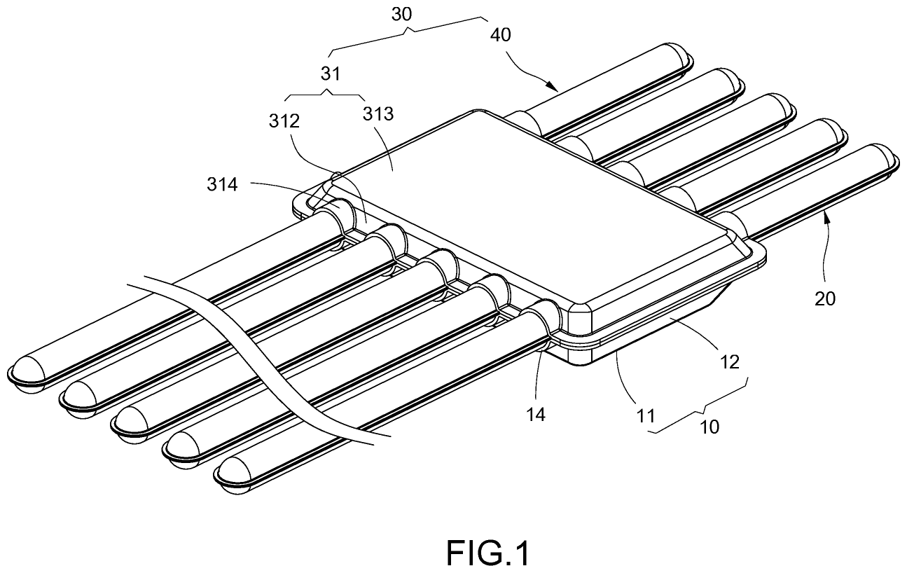

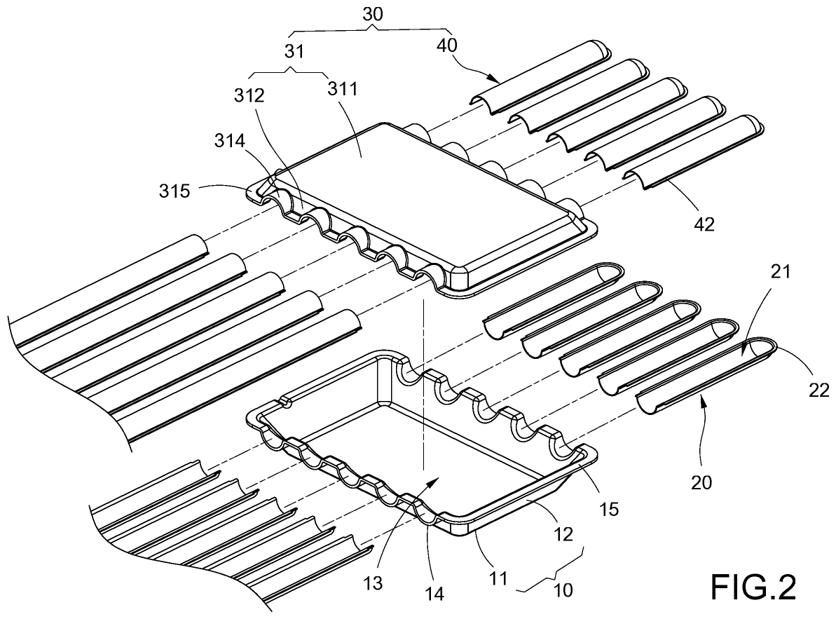

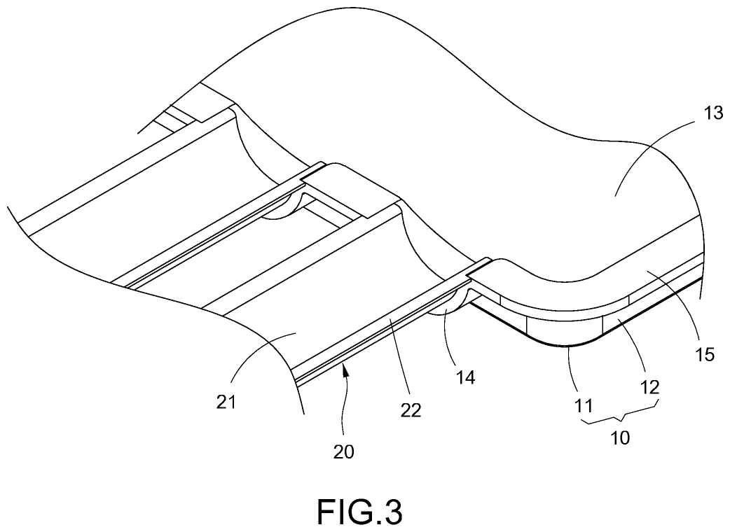

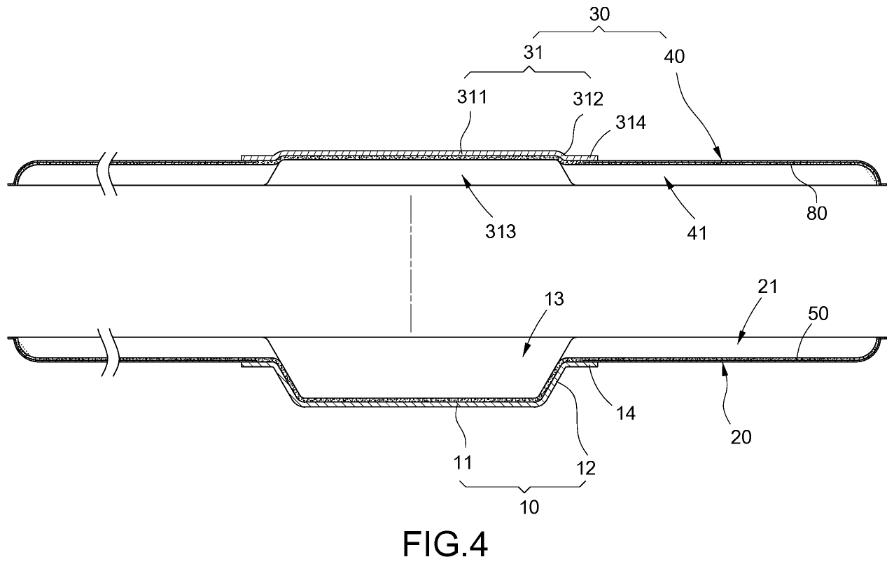

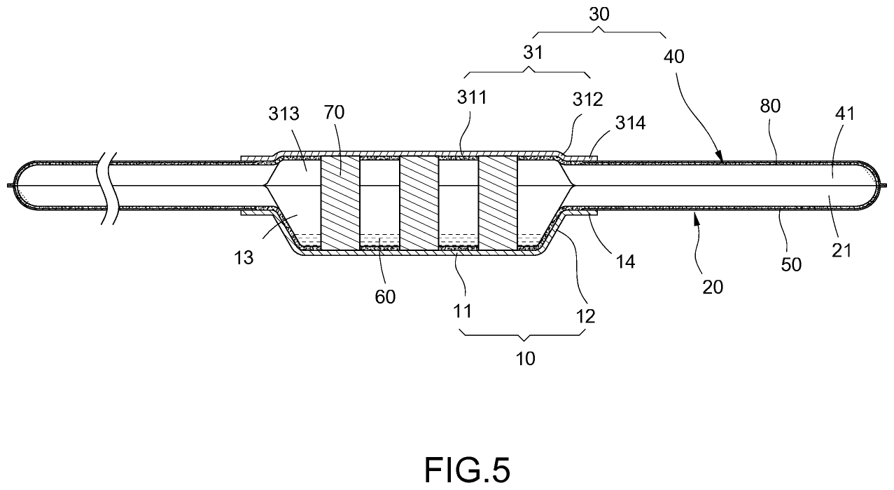

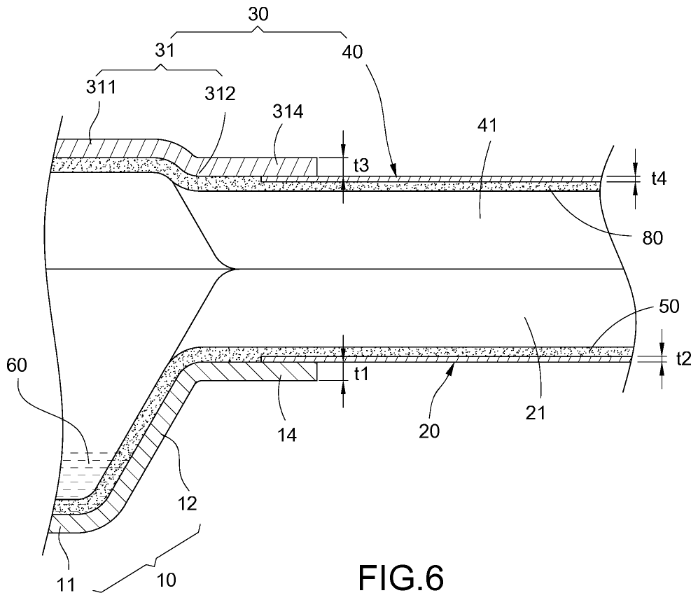

Please refer from FIG. 1 to FIG. 6, the present disclosure provides an assembly structure of a vapor chamber and a heat pipe including a vapor chamber half housing 10, a plurality of heat pipe half housings 20, a half housing covering component 30, a capillary structure 50 and a working fluid 60.

The vapor chamber half housing 10 is made of a material having a desirable heat conductivity, such as copper, aluminum, magnesium, or an alloy thereof. The vapor chamber half housing 10 is in a rectangular shape and mainly includes a bottom plate 11 and a lower surrounding plate 12 upwardly extended from a periphery of the bottom plate 11, and a vapor chamber room 13 is enclosed between the bottom plate 11 and the lower surrounding plate 12. A plurality of lower engaging half rings 14 are disposed at one side of the lower surrounding plate 12 away from and the bottom plate 11. The lower surrounding plate 12 is extended with a first folding edge 15.

Each of the heat pipe half housings 20 is correspondingly connected to each of the lower engaging half rings 14, and a cross sectional surface of each of the heat pipe half housings 20 is in a semi-circular shape. A heat pipe room 21 is formed in each of the heat pipe half housings 20, and each of the heat pipe rooms 21 communicates with the vapor chamber room 13. An opening end of each of the heat pipe half housings 20 is outwardly extended with a second folding edge 22.

The half housing covering component 30 is correspondingly connected and sealed with the vapor chamber half housing 10 and each of the heat pipe half housings 20. The half housing covering component 30 is made of a material having a desirable heat conductivity, such as copper, aluminum, magnesium, or an alloy thereof. The half housing covering component 30 mainly includes a vapor chamber half housing cover 31 and a plurality of heat pipe half housing covers 40. The vapor chamber half housing cover 31 is in a rectangular shape and mainly includes a top plate 311 and an upper surrounding plate 312 downwardly extended from a periphery of the top plate 311, and another vapor chamber room 313 is enclosed between the top plate 311 and the upper surrounding plate 312. A plurality of upper engaging half rings 314 are disposed at one side of the upper surrounding plate 312 away from the top plate 311. The upper surrounding plate 312 is extended with a third folding edge 315.

A cross sectional surface of each of the heat pipe half housing covers 40 is in a semi-circular shape. Another heat pip room 41 is formed in each of the heat pipe half housing covers 40. Each of the another heat pipe rooms 41 communicates with the another vapor chamber room 313. An opening end of each of the heat pipe half housing covers 40 is outwardly extended with a fourth folding edge 42.

The vapor chamber half housing cover 31 and the vapor chamber half housing 10 are interchangeable or commonly shared. Each of the heat pipe half housing covers 40 and each of the heat pipe half housings 20 are interchangeable or commonly shared.

In some embodiments, the vapor chamber half housing 10 has a plate thickness t1, and each of the heat pipe half housings 20 has a plate thickness t2. The plate thickness t2 of each of the heat pipe half housings 20 is less than the plate thickness t1 of the vapor chamber half housing 10 because the vapor chamber half housing 10 and each of the heat pipe half housings are formed through different punching manufacturing procedures. As such, each of the heat pipe half housings 20 has bigger heat pipe room 21 provided for air and fluid to flow therein. In some embodiments, the vapor chamber half housing cover 31 has a plate thickness t3, and each of the heat pipe half housing covers 40 has a plate thickness t4. The plate thickness t4 of each of the heat pipe half housing covers 40 is less than the plate thickness t3 of the vapor chamber half housing cover 30 due to being formed through different punching manufacturing procedures. As such, each of the heat pipe half housing covers 40 has bigger another heat pipe room 41 provided for air and fluid to flow therein.

The capillary structure 50 is continuously disposed on the vapor chamber half housing 10 and each of the heat pipe half housings 20 and formed in the vapor chamber room 13 and each of the heat pipe rooms 21. The above-mentioned “continuously disposed” is that the material of the capillary structure 50 evenly covers an inner surface of the bottom plate 11 and an inner surface of the lower surrounding plate 12, and a sintering process or a thermal diffusion soldering process is performed to make the capillary structure 50 be fixedly adhered on the inner surface of the bottom plate 11 and the inner surface of the lower surrounding plate 12, in other words the capillary structure 50 is integrally formed (or formed in one piece).

In some embodiments, the capillary structure 50 is made of a material having a desirable capillary absorbing capability, for example a metal woven net, porous sintering powders, or fiber bundles.

The working fluid 60 is pure water filled in the vapor chamber room 13. A gas exhausting (degassing) and sealing process is performed to make the vapor chamber room 13 and each of the heat pipe rooms 21 be a vacuum room.

In some embodiments, the assembly structure of vapor chamber and heat pipe provided by the present disclosure further includes a plurality of support columns 70. The plurality of support columns 70 are made of a material having a desirable heat conductivity, such as copper, aluminum, magnesium, or an alloy thereof. In some embodiments, the support column 70 is a solid circular column. Two end surfaces of each of the support columns 70 respectively abut against the bottom plate 11 and the top plate 311.

In some embodiments, the assembly structure of vapor chamber and heat pipe provided by the present disclosure further includes another capillary structure 80. The another capillary structure 80 is continuously disposed on the vapor chamber half housing cover 31 and each of the heat pipe half housing covers 40 and formed in the another vapor chamber room 313 and each of the another heat pipe rooms 41.

When being assembled, the first folding edge 15 of the vapor chamber half housing 10 is correspondingly adhered to the third folding edge 315 of the vapor chamber half housing cover 31. The second folding edge 22 of each of the heat pipe half housings 20 is correspondingly adhered to the fourth folding edge 42 of each of the heat pipe half housing covers 40. A soldering connecting process is performed to make the half housing covering component 30 be tightly sealed with the vapor chamber half housing 10 and each of the heat pipe half housing 20. The vapor chamber half housing 10 and the vapor chamber half housing cover 31 are assembled as a rectangular vapor chamber, and each of the heat pipe half housings 20 and each of the heat pipe half housing covers 40 are assembled as a circular heat pipe.

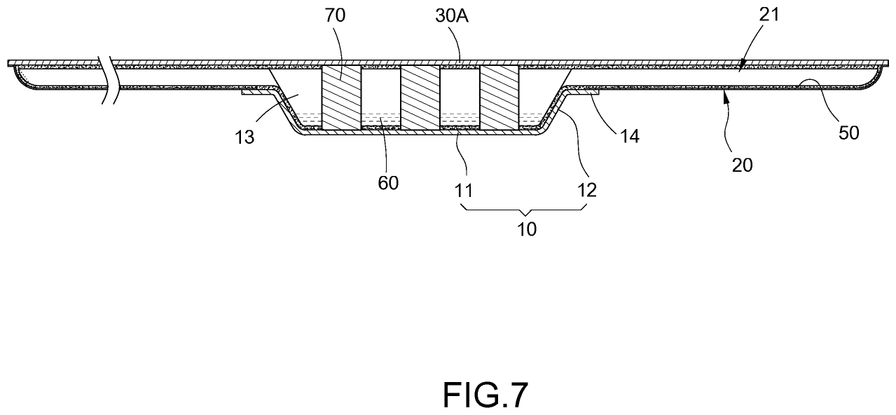

Please refer to FIG. 7, which discloses another embodiment of the assembly structure of the vapor chamber and the heat pipe provided by the present disclosure. A half housing covering component 30A is a flat plate. The half housing covering component 30A is correspondingly sealed with the vapor chamber half housing 10 and each of the heat pipe half housings 20. Each of the support columns 70 is vertically disposed between the vapor chamber half housing 10 and the half housing covering component 30A.

While this disclosure has been described by means of specific embodiments, numerous modifications and variations could be made thereto by those skilled in the art without departing from the scope and spirit of this disclosure set forth in the claims.

What is claimed is:

1. An assembly structure of a vapor chamber and a heat pipe, the assembly structure comprising:
a vapor chamber half housing, comprising a bottom plate and a lower surrounding plate upwardly extended from the bottom plate, wherein a vapor chamber room is enclosed between the bottom plate and the lower surrounding plate, and the lower surrounding plate comprises a plurality of lower engaging half rings;
a plurality of heat pipe half housings, correspondingly connected to each of the lower engaging half rings, wherein each of the heat pipe half housings comprises a heat pipe room communicating with the vapor chamber room;
a half housing covering component, correspondingly connected and sealed with the vapor chamber half housing and each of the heat pipe half housings;
a capillary structure, continuously disposed on the vapor chamber half housing and each of the heat pipe half housings and disposed in the vapor chamber room and each of the heat pipe rooms; and
a working fluid, filled in the vapor chamber room.

2. The assembly structure according to claim 1, wherein the half housing covering component comprises a vapor chamber half housing cover and a plurality of heat pipe half housing covers, the vapor chamber half housing cover comprises a top plate and an upper surrounding plate downwardly extended from the top plate, another vapor chamber room is enclosed between the top plate and the upper surrounding plate, the upper surrounding plate comprises a plurality of upper engaging half rings, each of the heat pipe half housing covers is correspondingly connected to each of the upper engaging half rings, each of the heat pipe half housing cover comprises another heat pipe room, and the another heat pipe room communicates with the another vapor chamber room.

3. The assembly structure according to claim 2, wherein the vapor chamber half housing comprises a first folding edge, each of the heat pipe half housings comprises a second folding edge, the vapor chamber half housing cover comprises a third folding edge, each of the heat pipe half housing covers has a fourth folding edge, the first folding edge is correspondingly connected with the third folding edge, and the second folding edge is correspondingly connected with the fourth folding edge.

4. The assembly structure according to claim 3, wherein the vapor chamber half housing and the vapor chamber half housing cover are assembled as a rectangular vapor chamber, and each of the heat pipe half housings and each of the heat pipe half housing covers are assembled as a circular heat pipe.

5. The assembly structure according to claim 2, further comprising another capillary structure, the another capillary structure is continuously disposed on the vapor chamber half housing cover and each of the heat pipe half housing covers and disposed in the another vapor chamber room and the another heat pipe room.

6. The assembly structure according to claim 5, wherein the another capillary structure is integrally formed.

7. The assembly structure according to claim 2, further comprising a plurality of support columns, and each of the support columns is vertically disposed between the vapor chamber half housing and the vapor chamber half housing cover.

8. The assembly structure according to claim 2, wherein a plate thickness of each of the heat pipe half housing covers is less than a plate thickness of the vapor chamber half housing cover.

9. The assembly structure according to claim 1, wherein the capillary structure is integrally formed.

10. The assembly structure according to claim 1, wherein a plate thickness of each of the heat pipe half housings is less than a plate thickness of the vapor chamber half housing.

11. The assembly structure according to claim 1, wherein the half housing covering component comprises a flat plate.

12. The assembly structure according to claim 11, further comprising a plurality of support columns, and each of the support columns is vertically disposed between the vapor chamber half housing and the half housing covering component.
